(19) United States
(12) Patent Application Publication
(10) Pub. No.: US 2025/0054854 A1
(43) Pub. Date: Feb. 13, 2025

(54) HEAVILY DOPED SEMICONDUCTOR DEVICES FOR POWER DISTRIBUTION

(71) Applicant: ADEIA SEMICONDUCTOR BONDING TECHNOLOGIES INC., San Jose, CA (US)

(72) Inventors: Rajesh Katkar, Milpitas, CA (US); Cyprian Emeka Uzoh, San Jose, CA (US); Belgacem Haba, Saratoga, CA (US)

(21) Appl. No.: 18/745,238

(22) Filed: Jun. 17, 2024

Related U.S. Application Data
(60) Provisional application No. 63/511,598, filed on Jun. 30, 2023.

(51) Int. Cl. H01L 23/498; H01L 21/48; H01L 23/00; H01L 23/46

(52) U.S. Cl. CPC H01L 23/49872; H01L 21/4857; H01L 23/46; H01L 23/49822; H01L 24/08; H01L 24/80; H01L 2224/08225; H01L 2224/80895; H01L 2224/80896

(57) ABSTRACT

A device including a first integrated device die and a semiconductor device. The first integrated device die can include a die insulating layer and a die conductive feature at least partially embedded in the die insulating layer. The semiconductor device can include a first insulating layer on the first surface, a device conductive feature at least partially embedded in the first insulating layer, and a first heavily doped semiconductor material electrically connected to the device conductive feature. The die conductive feature can be connected to power or ground through at least the first heavily doped semiconductor material.

### INCORPORATION BY REFERENCE

This application claims priority to U.S. Provisional Application No. 63/511,598, filed Jun. 30, 2023, and which is incorporated herein by reference. Any and all applications for which a foreign or domestic priority claim is identified in the Application Data Sheet as filed with the present application are hereby incorporated by reference under 37 CFR 1.57.

### BACKGROUND

### Field

The field relates to bonded structures, and, in particular, to bonded structures in which semiconductor materials are heavily doped for power distribution.

### Description of the Related Art

As features in semiconductor devices continue to shrink, power delivery issues are of increasing concern, as thermal issues, electrical isolation issues, limitations on feature sizes, losses due to traversing large numbers of metal layers, and so forth make it difficult to efficiently provide power to semiconductor devices. Accordingly, there remains a continuing need for improved power delivery devices.

### BRIEF DESCRIPTION OF THE DRAWINGS

The detailed description is set forth with reference to the accompanying figures. The use of the same numbers in different figures indicates similar or identical items.

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

FIG. 1A depicts a schematic side sectional view of power delivery device soldered to an integrated device die.

FIG. 1B depicts a schematic side sectional view of a power delivery device bonded with multiple integrated device dies and an interposer.

FIGS. 2A-2B depict a schematic side sectional view of a bonded structure including a semiconductor device comprising an interposer configured to deliver power to one or more integrated device dies.

FIGS. 3A-3D are schematic side section views of a semiconductor device with heavily doped semiconductor materials, according to various embodiments.

FIG. 4 is a schematic side sectional view of a semiconductor device with heavily doped semiconductor materials connected to a back surface of an integrated device die.

FIG. 5 is a schematic side sectional view of a semiconductor device with heavily doped semiconductor materials connected to a front surface of an integrated device die.

FIG. 6 is schematic side sectional view of a semiconductor device with heavily doped semiconductor materials connected to multiple integrated device dies and serving as an interposer, with power delivery supplied from a top side of the semiconductor device.

FIG. 7 is schematic side sectional view of a semiconductor device with heavily doped semiconductor materials connected to multiple integrated device dies and serving as an interposer, with power delivery supplied from a bottom side of the semiconductor device.

FIG. 8A is a schematic side sectional view of a semiconductor device with heavily doped semiconductor materials and cooling channels mounted to (e.g., directly hybrid bonded to) a back surface of an integrated device die.

FIG. 8B is a schematic top view of a semiconductor device with heavily doped semiconductor materials temperature controlled by cooling channels.

FIG. 9A is a schematic side sectional view of semiconductor elements prepared for direct hybrid bonding without an intervening adhesive.

FIG. 9B is a schematic side sectional view of a directly hybrid bonded structure without an intervening adhesive.

### DETAILED DESCRIPTION

Power distribution or power delivery devices may provide power to electronic components (such as integrated device dies) through the use of metal planes or metal lines that have high coefficients of thermal expansion (CTE). Metal planes within power delivery devices are formed of a thickness to support the power requirements of one integrated device die or a stack of integrated device dies. Consequently, stacked dies lack adequate power supply from the power delivery devices because of the limited power capabilities of the metal planes. In addition, the metal planes add thermomechanical stresses to the overall stack due to CTE differential between the die or die stack and the metal planes. Additionally, devices typically are limited by space for vias to be connected to the metal plane. Accordingly, there remains a continued need for improved power distribution or delivery devices.

Providing the correct amount of power to one or multiple integrated device dies can be challenging. In particular, some power delivery devices use metal planes to supply power and ground to the integrated device die. For example, metal planes can be used as panel-level redistribution layers (RDL). An RDL may be a multi-die power deliver vehicle/structure made as a panel that is used to provide power delivery. Metal planes have a high CTE which causes the metal to expand as it heats up. The expansion of the metal plane within the power delivery device creates a high degree of mechanical and thermal strain on the device and/or on the bonds that connect the power pathways. To reduce or prevent the strain on the power delivery device, the metal planes are often kept to lower temperatures, limiting the power they can supply. Increasing the size of the metal planes to allow higher current while limiting the temperature can increase the impact of the high CTE and physical stress caused by the high CTE. Additionally, there is a design advantage to decreasing the thickness of the RDL layers to allow for more layers in the same, limited space. Metal RDL planes, because of the CTE limitations and space requirements, may not be thick enough for power delivery to be provided to both sides of (e.g., the top and bottom sides of) the power delivery device. Additionally, the power may be insufficient for stacking multiple integrated device dies to be powered by the power delivery device.

Additionally, each additional power connection uses a metal via to connect the metal plane to the integrated device die. The finite amount of space creates a limitation on the number of connections (power, signal, and/or ground connections) that can be made between the power delivery device and the integrated device die. In particular, in some devices, power, ground, and signal connections are made at the front active side of the chip. In such devices, the power and ground connections occupy valuable real estate in the routing layers that reduces the number of signal lines that can be connected to the active circuitry at the front surface. Attempts to overcome these challenges have included adding an interposer layer in the power delivery device. Such attempts have found the metal lacking the thickness required to provide good power. Additionally, an interposer layer does not eliminate the space constraints that limit the number of connections that can be made with vias.

Beneficially, the embodiments disclosed herein address these challenges by providing methods and structures for utilizing heavily doped semiconductor materials within a semiconductor power delivery device to provide power and ground to an integrated device die. In some embodiments, the semiconductor power delivery device can be bonded (e.g., directly hybrid bonded) to a back surface of the die opposite the active front surface of the die. In such embodiments, the backside connection to the die can allow for an increased number of signal connections at the front surface (which can comprise an active surface) of the die. In other embodiments, the semiconductor power delivery device can be bonded (e.g., directly hybrid bonded) to the active front surface of the die. The disclosed embodiments can maintain multiple electrical potentials, including power and/or ground, while better utilizing limited space and preventing thermal stresses.

In some examples, a semiconductor device, comprising: a first layer comprising a first heavily doped semiconductor material and a first insulating bonding layer; a second layer comprising a second heavily doped semiconductor material and a second insulating bonding layer; and a first via extending through the second layer and electrically connecting to the first heavily doped semiconductor material, wherein the first layer and the second layer are directly bonded to one another without an intervening adhesive.

In some examples, the semiconductor device, wherein the first via connects one of power or ground to the first heavily doped semiconductor material of the first layer. In some examples, the semiconductor device, wherein the first layer further comprises first conductive features and the second layer further comprises second conductive features, wherein the first conductive features and the second conductive features are directly bonded to one another without an intervening adhesive. In some examples, the semiconductor device, wherein the second layer is hybrid bonded to the first layer such that the second insulating bonding layer of the second layer is directly bonded to the first insulating bonding layer of the first layer, and the second conductive features of the second layer are directly bonded to the first conductive features of the first layer.

In some examples, the semiconductor device, further comprising a third layer comprising a third heavily doped semiconductor material and a third insulating bonding layer, wherein the second layer and the third layer are directly bonded to one another without an intervening adhesive. In some examples, the semiconductor device, further comprising insulating rings around the first via of the first layer. In some examples, the semiconductor device, wherein the first heavily doped semiconductor material is embedded with dielectric spacers, the dielectric spacers separating the first heavily doped semiconductor material into heavily doped semiconductor islands. In some examples, the semiconductor device, wherein a first heavily doped semiconductor island of the heavily doped semiconductor islands is connected to a first power source at a first voltage and a second heavily doped semiconductor island of the heavily doped semiconductor islands is connected to ground.

In some examples, the semiconductor device, wherein the heavily doped semiconductor islands are configured to connect to different electrical potentials. In some examples, the semiconductor device, wherein the second heavily doped semiconductor material is connected to electrical ground. In some examples, the semiconductor device, wherein the first heavily doped semiconductor material includes an insulating end cap. In some examples, the semiconductor device, wherein each of the first and second heavily doped semiconductor material has a dopant concentration of at least 10¹⁸ atoms/cm3 and less than 10²² atoms/cm3. In some examples, the semiconductor device, further comprising: a fluid inlet; an inlet channel connected to the fluid inlet; a fluid outlet; an outlet channel connected to the outlet; and one or more cooling channels extending through at least the first insulating layer, wherein the one or more cooling channels connect to the inlet channel and the outlet channel.

In some examples, the semiconductor device, wherein the inlet, the inlet channel, and the one or more cooling channels are arranged to allow a fluid to flow into the semiconductor device such that the inlet channel and the one or more cooling channels integrally connect such that the fluid can flow from the inlet channel to the one or more cooling channels. In some examples, the semiconductor device, wherein the outlet, the outlet channel, and the one or more cooling channels are arranged to allow a fluid to flow from the semiconductor device such that the one or more cooling channels and the outlet channel integrally connect such that the fluid can flow from the one or more cooling channels to the outlet channel to exit the semiconductor device at the outlet. In some examples, the semiconductor device, wherein the inlet, the inlet channel, the outlet, the outlet channel, and the one or more cooling channels include a cavity, wherein the cavity encloses a cooling fluid.

In some examples, the semiconductor device, wherein the cooling fluid is a dielectric fluid. In some examples, the semiconductor device, wherein the inlet, the inlet channel, the outlet, the outlet channel, and the one or more cooling channels include a cavity and a barrier surrounding the cavity, wherein the barrier separates the cavity from the first insulating bonding layer. In some examples, a bonded structure including the semiconductor device, the bonded structure further comprising an integrated device die, the integrated device die comprising a front surface and a back surface, wherein the semiconductor device is directly bonded to the integrated device die.

In some examples, a bonded structure comprising: a first integrated device die comprising a front surface and a back surface, the first integrated device die including a die insulating layer and a die conductive feature at least partially embedded in the die insulating layer; and a semiconductor device having a first surface and a second surface opposite the first surface, the semiconductor device including a first insulating layer on the first surface, a device conductive feature at least partially embedded in the first insulating layer, and a first heavily doped semiconductor material electrically connected to the device conductive feature, the first insulating layer directly bonded to the die insulating layer without an intervening adhesive, and the die conductive feature directly bonded to the device conductive feature without an intervening adhesive, wherein the die conductive feature is connected to power or ground through at least the first heavily doped semiconductor material.

In some examples, the bonded structure, wherein the front surface of the first integrated device die is an active side that includes one or more transistors, the one or more transistors being disposed nearer the front surface than the back surface. In some examples, the bonded structure, wherein the semiconductor device is directly bonded to the back surface of the first integrated device die without an intervening adhesive. In some examples, the bonded structure, wherein the semiconductor device includes a second heavily doped semiconductor material disposed over the first heavily doped semiconductor material.

In some examples, the bonded structure, wherein the first heavily doped semiconductor material is connected to one of a first power or ground and the second heavily doped semiconductor material is connected to one of a second power or ground, the first and second heavily doped semiconductor materials electrically connected to the first integrated device die. In some examples, the bonded structure, further comprising a via extending through the first heavily doped semiconductor material, the via electrically connecting the die conductive feature to the second heavily doped semiconductor material. In some examples, the bonded structure, further comprising a second integrated device die with a second insulating layer on a back surface of the second integrated device die, the second integrated device die directly bonded with the semiconductor device on a side opposite the first integrated device die.

In some examples, the bonded structure, wherein the first heavily doped semiconductor material is an electrically conductive material with a coefficient of thermal expansion (CTE) of the first heavily doped semiconductor material within 50% to 150% of a CTE of device portion of the first integrated device die. In some examples, the bonded structure, further comprising: a fluid inlet; an inlet channel connected to the fluid inlet; a fluid outlet; an outlet channel connected to the outlet; and one or more cooling channels extending through at least the first insulating layer, wherein the one or more cooling channels connect to the inlet channel and the outlet channel. In some examples, the semiconductor device, wherein the inlet, the inlet channel, and the one or more cooling channels are arranged to allow a fluid to flow into the semiconductor device such that the inlet channel and the one or more cooling channels integrally connect such that the fluid can flow from the inlet channel to the one or more cooling channels.

In some examples, the semiconductor device, wherein the outlet, the outlet channel, and the one or more cooling channels are arranged to allow a fluid to flow from the semiconductor device such that the one or more cooling channels and the outlet channel integrally connect such that the fluid can flow from the one or more cooling channels to the outlet channel to exit the semiconductor device at the outlet. In some examples, the semiconductor device, wherein the inlet, the inlet channel, the outlet, the outlet channel, and the one or more cooling channels include a cavity, wherein the cavity encloses a cooling fluid. In some examples, the semiconductor device, wherein the cooling fluid is a dielectric fluid. In some examples, the semiconductor device, wherein the inlet, the inlet channel, the outlet, the outlet channel, and the one or more cooling channels include a cavity and a barrier surrounding the cavity, wherein the barrier separates the cavity from the first insulating bonding layer.

In some examples, a method, comprising: depositing a first insulating bonding layer on a heavily doped semiconductor material; at least partially embedding conductive features in the first insulating bonding layer; and preparing the first insulating bonding layer for hybrid bonding with an electronic component, wherein the heavily doped semiconductor material has a coefficient of thermal expansion (CTE) within 50% to 150% of a CTE of a device portion of the electronic component. In some examples, the method, further comprising directly bonding a second insulating bonding layer of the electronic component to the first insulating bonding layer and directly bonding a second conductive feature of the electronic component to a first conductive feature at least partially embedded in the first insulating bonding layer. In some examples, the method, wherein the heavily doped semiconductor material comprises a heavily doped semiconductor material.

In some examples, a bonded structure comprising: a heavily doped semiconductor material having a first insulating bonding layer on a first surface of the heavily doped semiconductor material and first conductive features at least partially embedded in the first insulating bonding layer; and an electronic component having a second insulating bonding layer and second conductive features at least partially embedded in the second insulating bonding layer, the first insulating bonding layer directly bonded with the second insulating bonding layer without an intervening adhesive, the first conductive features directly bonded with the second conductive features without an intervening adhesive, wherein the heavily doped semiconductor material has a coefficient of thermal expansion (CTE) within 50% to 150% of a CTE of a device portion of the electronic component. In some examples, the bonded structure, wherein the heavily doped semiconductor material comprises a heavily doped semiconductor material.

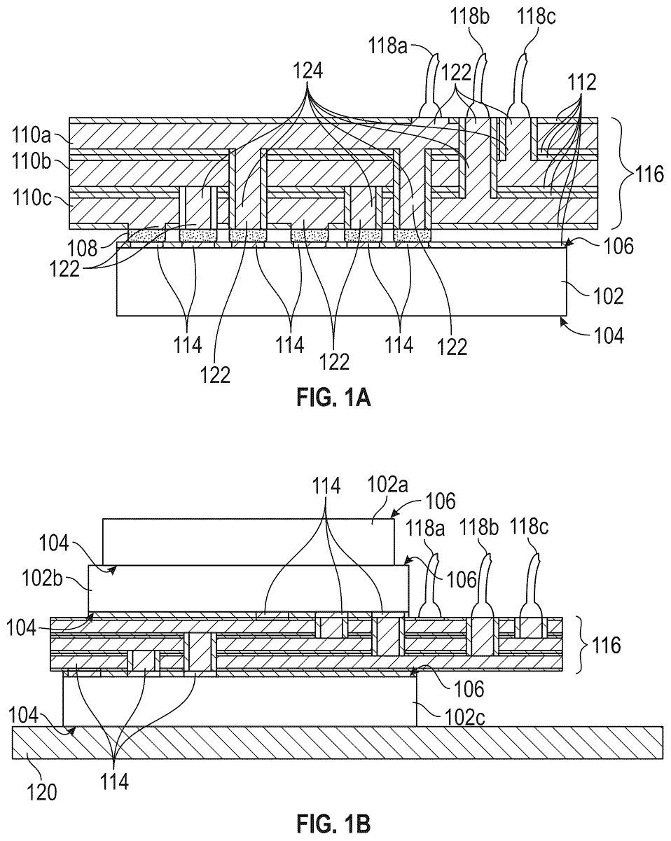

FIG. 1A depicts a schematic side sectional view of a power delivery device 116 soldered to a back surface 106 opposite a front surface 104 of an integrated device die 102. The front surface 104 can be an active side, e.g., in which one or more transistors are nearer to the active front surface 104 than to the back surface 106. In the illustrated device 116, power within the device 116 is routed to the integrated device die 102 by metal planes 110 (e.g., planes 110a-110c) separated by insulating layers 112. The metal planes 110 are connected to electrical connectors 118 (e.g., bonding wires) individually by way of upper conductive contact features or pads 122 to provide a first power from an electrical connector 118a at the metal plane 110a, a ground from an electrical connector 118c at the metal plane 110b, and a second power from an electrical connector 118b at the metal plane 110c. The metal planes 110 and the insulating layers 112 are patterned so as to route power and ground to the corresponding pads 114 on the integrated device die 102. The conductive pads 114 on the die and the conductive pads 122 on the bottom side of the device 116 can connect through the use of solder 108. The conductive pads 114, 122 can comprise a suitable metal, such as copper, nickel, gold, etc. The metal pads 122 on the die 102 can connect the lower metal plane 110c in a continuous manner (e.g., the pad 122 can be directly connected to metal layer of the plane 110c). The pads 114 of the die 102 can electrically connect to the upper and middle metal planes 110a, 110b through the use of conductive vias 124 (e.g., metal vias). Together, the metal pads 114, 122 and the vias 124 provide the power and ground from the metal planes 110 to the integrated device die 102. The metal planes 110 receive power from the electrical connectors 118 that are attached to the metal pads 122 and the vias 124 as needed to pass electrical potential from the electrical connectors 118 to the metal planes 110. For example, the electrical connector 118a provides a first electrical potential (e.g., a first power level) to the metal plane 110a through the metal pad 122, the electrical connector 118c connects the metal plane 110b to a second electrical potential (e.g., electrical ground) using the metal pad 122 and the via 124, and the electrical connector 118b provides a third electrical potential (e.g., a second power level) to the metal plane 110c through the metal pad 122 and the via 124. The metal planes 110 are connected to the integrated device die 102 using bonding methods, such as the solder 108, that connects the metal pads 122 of the device 116 to the metal pads 114 on the back surface of the integrated device die 102. The power supplied by the device 116 to the conductive pads 114 at the back surface 106 of the integrated device die 102 can be carried to the transistors and the devices at the front surface 104 using through substrate vias or through silicon vias (TSVs), not shown in FIG. 1A. These TSVs may be through vias or blind vias (e.g., power visa, nano-TSVs, etc.) providing power to the transistors.

In FIG. 1A, the metal pads 114 and 122 and the metal planes 110 are made from one or more metals (such as copper, with a CTE of approximately 17 ppm/° C.) that have high CTE. The devices and materials (e.g., semiconductor or dielectric materials) to which the metal planes 110 and the metal pads 114 and 122 attach generally have a lower CTE, for example, in a range of 0.2 ppm/° C. to 5 ppm/° C. The mismatch in CTE causes the metal to expand differently than the devices and materials to which the metal planes 110 and the metal pads 114 and 122 are attached as the temperature increases. For example, as the metal planes 110 conduct electricity to provide power from the device 116 to the integrated device die 102, the metal pads 114 heat up and expand with the metal planes 110, creating strain on the solder joints connecting the metal pads 114 to the integrated device die 102 (and strain in the device 116 and device die 102) that is expanding at a lower rate. Such strain can damage the device 116, the die 102, and/or the solder 108 or other connections that connect the device 116 and the integrated device die 102.

Further, in devices as shown in FIG. 1A, relying on the metal planes 110 alone may not provide sufficient power to support power distribution to the integrated device dies 102 to more than one side of the device 116. FIG. 1B depicts a schematic side sectional view of the device 116 bonded with multiple integrated device dies 102 and a substrate 120. An integrated device die 102c can be mounted to the substrate 120, and a bottom side of the power delivery device 116 can be mounted on the integrated device die 102c. An integrated device die 102b can be mounted on an upper side of the power delivery device 116, and an integrated device die 102a can be mounted on the integrated device die 102b. In various embodiments, the power delivery device 116 can serve as an interposer that enables the ability to power the integrated device dies 102 from top and bottom sides of the device 116. For example, the device 116 can be bonded with a front surface 104 of the integrated device die 102b. The integrated device die 102a can be bonded to the back surface 106 of the integrated device die 102b that is connected to the device 116. The integrated device die 102c can be bonded by a back surface 106 to the device 116 and attached to the substrate 120. In this arrangement, the device 116 can function as an interposer to connect the integrated device dies 102 together electrically, e.g., to provide electrical potential (power and/or ground) to the dies. In FIG. 1B, the dies 102b, 102c can be direct hybrid bonded to the power delivery device 116, and the die 102a can be direct hybrid bonded to the die 102b. In some embodiments, the die 102c can be direct hybrid bonded to the substrate 120. In other embodiments, other bonding methods (such as flip chip or solder bonding, or thermocompression bonding) can be used. Although not shown in FIG. 1B, it should be appreciated that the dies 102 (e.g., dies 102b, 102c) can comprise through substrate vias (TSVs) to convey signals and/or power/ground through the dies 102b, 102c.

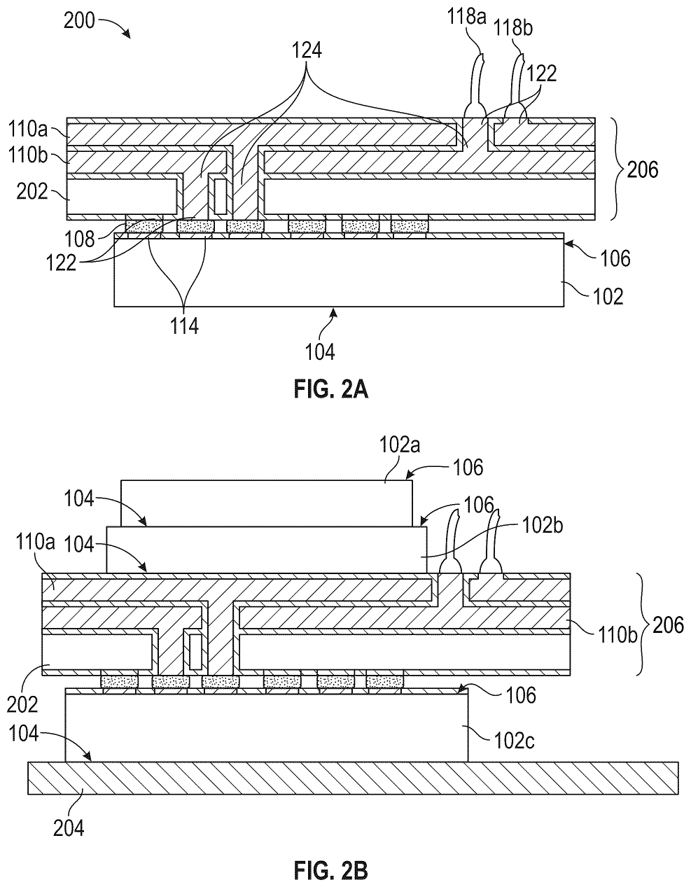

FIGS. 2A and 2B show examples of power delivery devices 206 configured to supply power from the metal planes 110 within the device 206 to the die 102. Specifically, FIGS. 2A-2B depict a schematic side sectional view of a bonded structure 200 including a device 206 with an embedded interposer 202. As explained above, the device 206 utilizes metal planes 110 as RDLs to distribute power and/or ground to the integrated device die 102. A first metal plane 110a is supplied with a first power level (e.g., a non-zero potential difference or voltage) from an electrical connector 118b. The metal plane 110b is connected to the electrical potential of the electrical connector 118a. The integrated device die 102 receives the first power level from the power delivery device 206 from the via 124 that connects the metal plane 110a to the metal pad 122 that is connected to electrical connector 118b. The current passes through a metal pad 122 that is connected to metal pad 114 of the die 102 using, for example, the solder 108 to connect the device 206 to a back surface 106 of the integrated device die 102. The back surface 106 of the integrated device die 102 is opposite the front surface 104 of the integrated device die 102. The front surface 104 can be an active side that includes one or more transistors, where the one or more transistors are disposed nearer the front surface 104 than the back surface 106.

The embedded interposer 202 is also connected to the integrated device die 102 using the solder 108. In some embodiments, the embedded interposer connects the devices and provide additional power and ground connections. In various embodiments, the interposer 202 can comprise a semiconductor material, a dielectric material, etc.

FIG. 2B depicts a power delivery device 206 stacked with multiple integrated device dies 102a-102c. In addition to the embedded interposer 202, the stack includes a substrate 204 connected to the front surface 104 of the integrated device die 102c. For example, the device 206 is bonded (e.g., by way of solder balls as shown) with a front surface 104 of an integrated device die 102b. An additional integrated device die 102a is bonded to the back surface 106 of the integrated device die 102b that is mounted on device 206. A third integrated device die 102c is bonded at a back surface 106 to the device 206 and is attached to an interposer 202 at a front surface 104 of the integrated device die 102c.

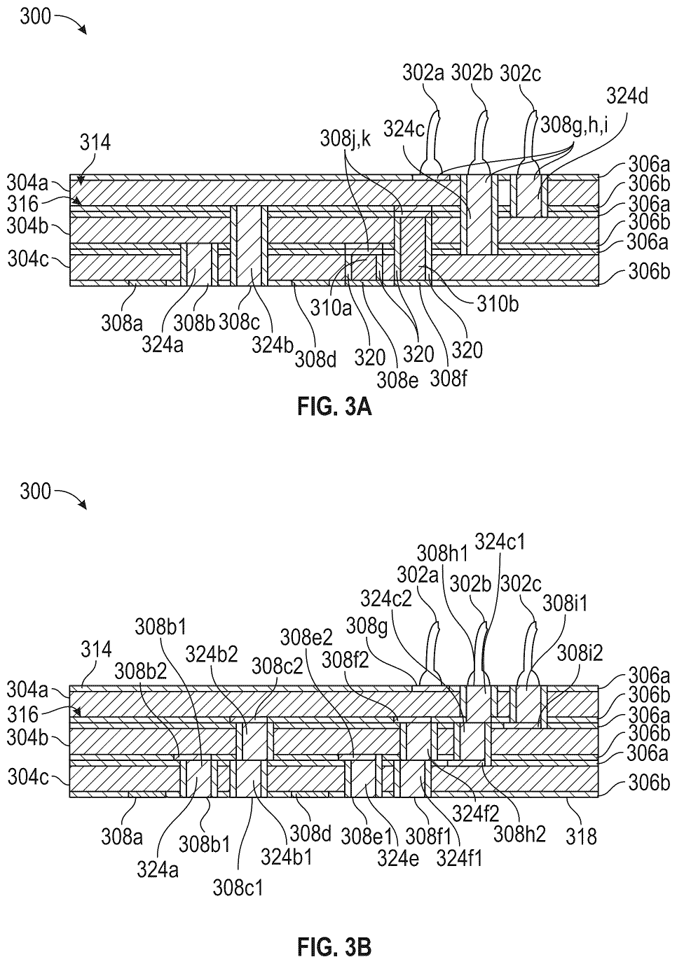

FIGS. 3A-3D are schematic side section views of a semiconductor device 300 with highly or heavily doped semiconductor materials, according to various embodiments. FIG. 3A depicts a semiconductor power delivery device 300 with layers of heavily doped semiconductor materials 304 e.g., semiconductor material 304. As explained herein, heavily the doped semiconductor materials 304 (e.g., semiconductor material layers 304a-304c) can be configured to route electrical potential inputs 302 (e.g., input power 302a and 302b and/or input ground 302c) to an integrated device die (not shown in FIG. 3A). In some embodiments, the heavily doped semiconductor material 304 can comprise a conductively doped material that serves as an electrical conductor. In some embodiments, the heavily doped semiconductor material can comprise a degenerate semiconductor material (e.g., degenerate silicon). In some embodiments, the heavily doped semiconductor material 304 can comprise a semiconductor material having a dopant level that is at least 1 dopant atom per 10,000 semiconductor material atoms (e.g., when the silicon density is 10²² atoms/cm³, the dopant density can be at least 10¹⁸ atoms/cm³). In some embodiments, the dopant level is at least 1 dopant atom per 10,000 semiconductor material atoms and less than 1000 dopant atoms per 10,000 semiconductor material atoms. In some embodiments, the dopant concentration is at least 1 dopant atom per 10,000 semiconductor material atoms and less than 100 dopant atoms per 10,000 semiconductor material atoms. For example, intrinsic crystalline Si (having about 5×10²² atoms/cm³), with an impurity doping concentration of 10¹⁸ atoms/cm³ or greater at room temperature may be considered conductive Si, with higher doping concentrations resulting in higher electrical conductivity. In some examples, the heavily doped semiconductor material 304 can have a dopant concentration of at least 10¹⁸ atoms/cm³ and less than 10²² atoms/cm³. In some embodiments, the semiconductor material 304 can be doped with impurities like boron to create p-type semiconductor, or phosphorus to create n-type semiconductor or any other suitable elements and compounds that increase conductivity. In some embodiments, a semiconductor material such as undoped silicon (e.g., single crystal Si or poly-Si) having a high resistance and low conductivity can be turned into a heavily doped semiconductor material with lower resistance and high conductivity. Doping the semiconductor material 304 increases the conductivity of the semiconductor material 304 allowing the semiconductor material 304 to serve as an electrical bus to provide power and/or ground to attached device dies.

The semiconductor material 304 can be, in some embodiments, doped to cause the semiconductor material 304 to be electrically conductive such that it can support providing electrical potential to electronic devices. For example, in some embodiments a semiconductor material 304 may be doped to enable the semiconductor material 304 to maintain an electrical potential such as power or ground. In some embodiments, one or more passive devices (e.g., capacitors, inductors, resistors, etc.) can be formed in the device 300. The passive devices can be integrated into the power delivery device 300 to further condition the power for delivery to the device die(s).

The semiconductor device 300 may be, in some embodiments, created using direct bonding without the use of an intervening adhesive. The semiconductor material 304 can be, in some embodiments, part of a layer that includes a semiconductor material 304 and one or more insulating bonding layers 306. Insulating bonding layers 306 can be deposited on front and back surfaces of the semiconductor material layers 304a-304c. In some embodiments, the insulating bonding layers 306a can be deposited on a top surface 314 of the semiconductor material 304a and a bottom surface 316 of the semiconductor material 304a. Insulating bonding layer 306 electrically separates the semiconductor material 304a from the rest of the semiconductor device 300.

In some embodiments, the semiconductor device 300 can include more than one heavily doped semiconductor material 304. In some embodiments, the heavily doped semiconductor material 304 is any electrically conductive material with a CTE of the heavily doped semiconductor material within 50% to 200%, 50% to 150%, 25% to 150%, or, 50% to 100% of a CTE of a device portion of the integrated device die (such as die 102, not shown in FIG. 3A). In some embodiments, the CTE of the heavily doped semiconductor material can be approximately one half to double the CTE of the device portion of the integrated device die. For example, for silicon with a CTE of 3 ppm/° C., the range of CTE of the heavily doped semiconductor material may be from 1.5 ppm/° C. to 6 ppm/° C. or may be from 2.5 ppm/° C. to 3 ppm/° C. Semiconductor material 304a can be a first doped material, semiconductor material 304b can be a second doped material, and semiconductor material 304c can be a third doped material. The heavily doped materials of semiconductor material layers 304a, 304b, and 304c can be, in some embodiments, the same material (with the same or different amount of dopants) or a different material separated into separate layers. The semiconductor materials 304a-304c can comprise any suitable type of semiconductor material, such as silicon, germanium, silicon germanium, or any other suitable semiconductor. In some embodiments, the semiconductor materials 304a,304b, and 304c can be doped to be electrically conductive. The semiconductor materials 304a and 304b can each have insulating bonding layers 306a deposited on a top surface 314 and insulating bonding layers 306b deposited on a bottom surface 316 wherein the insulating layer 306b deposited on the bottom surface 316 of the first semiconductor material 304a directly bonds with the insulating bonding layer 306a on the top surface 314 of the second semiconductor material 304b. Similarly, the insulating bonding layer 306b deposited on the bottom surface 316 of the second semiconductor material 304b directly bonds with the insulating bonding layer 306a on the top surface 314 of the third semiconductor material 304c. The semiconductor device 300 may be formed by damascene or non-damascene methods or combinations of both.

The semiconductor device 300 can electrically connect to the integrated device die (not shown) through conductive contact features 308a-308f at least partially embedded in the insulating bonding layer 306b. The conductive contact features 308a-308f can comprise discrete conductive contact pads or exposed ends of conductive vias (e.g., metallic vias 324). The contact features 308a-308f can comprise a metal, such as copper. For example, the third semiconductor layer 304c can electrically connect to a second electrical component (such as an integrated device die) using the conductive contact feature 308a embedded in the insulating layer 306b deposited on the bottom surface 316 of the third semiconductor material 304c. The first semiconductor layer 304a can electrically connect to an underlying second component (such as an underlying integrated device die 102) using a conductive via (e.g., a metallic via 324b) and conductive contact feature 308c embedded exposed at the insulating layer 306b deposited on the bottom surface 316 of the third semiconductor material 304c. The second semiconductor layer 304b can electrically connect to an underlying second component (such as an integrated device die) using a metallic via 324a and conductive contact feature 308b embedded at the insulating layer 306b deposited on the bottom surface 316 of the third semiconductor material 304c. The conductive contact features 308 are exposed on the bottom of the semiconductor device 300 which together, with the bonding layer 306, create a hybrid bonding surface 318 to bond with an electronic device such as the integrated device die 102.

The semiconductor device 300 further includes electrical pathways such as electrical potential inputs 302, metal conductive contact features 308, heavily doped semiconductor vias 310 (e.g., semiconductor vias 310a, 310b), and/or conductive metal vias 324 (e.g., metal vias 324a-324d). Inputs 302 can be used to provide electric potential (e.g., power and/or ground) to the heavily doped semiconductor materials 304. Conductive contact features 308g-308i connect with inputs 302a-c and may be situated as to connect with a corresponding heavily doped semiconductor material 304. For example, heavily doped semiconductor material 304b can be connected to ground by an input 302c, conductive contact feature 308i and via 324d and can connect ground to the underlying die (not shown) using, e.g., a metallic via 324a and metal conductive contact features 308b. In some embodiments, the heavily doped semiconductor material layer 304b can connect to the die by way of a heavily doped semiconductor via 310a and conductive contact feature 308e. To prevent heavily doped semiconductor materials 304a and 304c from electrically shorting to the vias 324a and 324d, conductive contact features 308b, 308e, and 308i, and/or doped semiconductor material via 310a, the vias 324a, 324d can be insulated by rings 320 of an insulating material, which may be different from or the same as the material used in the insulating bonding layers 306. In various embodiments, the insulating rings 320 can comprise an inorganic dielectric such as silicon oxide, silicon nitride, etc. In some other embodiments, the insulating rings can comprise an organic material.

The rings 320 may extend through the heavily doped semiconductor layer 304a, 304b, 304c to allow vias 324 or 310 to electrically connect to one layer and no other layers. For example, the doped semiconductor material via 310b can be insulated by a ring 320 to prevent electrical connection with layers 304b and 304c. The metal via 324b can be electrically connected to the heavily doped semiconductor material 304a and can deliver power through the conductive feature 308c without distributing the power to other layers. In some embodiments, a first conductive contact feature 308g delivers one of power or ground (e.g., a first power level) to the first heavily doped semiconductor material 304a of the first layer from a bonding wire connected to the input 302a. In some embodiments, a conductive barrier layer (not shown) may be disposed between the heavily doped semiconductor materials and the metallic conductors. For example, a conductive barrier later may be disposed between the heavily doped semiconductor materials 304b and the metallic conductors 324a.

Similar to the power delivery conductive contact features 308a-308c and vias 324a-324b, 310a-310b, the inputs 302 can provide power to a specific heavily doped semiconductor material 306 without other heavily doped semiconductor materials 306 receiving the power or ground input from that input. For example, the input 302b insulated by a ring 320 can provide power or ground through the heavily doped semiconductor layers 304a and 304b to provide input power to heavily doped semiconductor layer 304c without shorting to heavily doped semiconductor layers 304a and 304b.

In some embodiments, some or all conductive contact features may be made from doped semiconductor material. The heavily doped semiconductor material vias 310 of FIG. 3A can comprise conductive vias that provide electrical pathways that connect the heavily doped semiconductor materials 304 to conductive contact features 308d-308f to deliver power and/or ground between the inputs 302 and an integrated device die (such as die 102). The heavily doped semiconductor material vias 310 and the metal vias 324 can be insulated by dielectric rings 320 to prevent shorting. For example, doped semiconductor material via 310b extends through heavily doped semiconductor materials 304b and 304c to electrically connect to heavily doped semiconductor material 304a. Additionally, doped semiconductor material via 310a extends through heavily doped semiconductor material 304c to electrically connect to heavily doped semiconductor material 304b. The doped semiconductor material vias 310a and 310b are hybrid bonded to the heavily doped semiconductor materials 304b and 304a respectively through the contacts 308j and 308k to create an electrical connection to pass the electrical potential through the doped semiconductor material vias 310a and 310b to the heavily doped semiconductor materials 304b and 304a.

In some embodiments, one or more of the metal vias 324 and doped semiconductor vias 310 may be formed in the semiconductor device 300 after the layers 304a-304c have been directly bonded, in a via last process or via middle process. For example, once the insulating bonding layers 306 have been deposited on individual heavily doped semiconductor materials 304 and have been bonded together using techniques such as direct bonding, trenches for the metal vias 324, and heavily doped semiconductor vias 310, and the insulating rings 320 can be formed (e.g., etched or drilled) into the layers. In some embodiments the rings 320 can be deposited on the inside surface of the trenches after which the conductive contact features can be electroplated or deposited to be within the rings 320. In the embodiment of FIG. 3A, the layers 304a-304c can be directly bonded using a dielectric-to-dielectric bonding technique (e.g., such that only insulating layers 306a, 306b are directly bonded together). In some embodiments, only insulating bonding layers 306a, 306b can be directly bonded to one another, as the vias and pads (e.g., conductive contact features) can be formed after direct bonding. In other embodiments, as explained herein, the vias and conductive contact features can be formed within each layer 304a-304c before bonding, and the layers can be hybrid bonded to one another after forming the conductive contact features.

The semiconductor device 300 with the layers of semiconductor material 304 that are doped to be electrically conductive can provide the advantage of power application through vias 324, 310 without the disadvantages of metal planes. For example, the CTE of the semiconductor device 300 can be closer to the CTE of a connected electronic device, e.g., the integrated device die 102. As heat increases due to power usage, the semiconductor device 300 and the electronic devices can expand together which lessens the mechanical strain on the components and connection points.

FIG. 3B depicts a semiconductor device 300 with layers of heavily doped semiconductor material 304 and insulating bonding material 306 bonded together using a direct hybrid bonding technique. Unless otherwise noted, the components of FIG. 3B may be the same as or substantially similar to like-numbered components of FIG. 3A. Electrical potential can be provided to and from the heavily doped semiconductor materials 304 through conductive contact features 308 and vias 324, 310. Portions of the vias 324 can be separately provided in each layer 304a-304c prior to bonding so that each section extends through a corresponding heavily doped semiconductor material layer 304. The semiconductor material layers 304a-304c can be direct hybrid bonded together such that the insulating bonding layers 306a, 306b are directly bonded together and such that opposing conductive contact features (whether exposed ends portions of the vias 324 or discrete pads) are also directly bonded together. The conductive contact features can connect to an external device such as a lower integrated device die (such as lower die 102 not pictured) and/or an upper component, such as an upper integrated device die, a power supplying device, etc.

In various embodiments, for example, conductive contact feature 308c1 can comprise an exposed end portion of a first via section 324b1 that extends through heavily doped semiconductor material 304c. The upper exposed portion of first via section 324b1 can be directly bonded and electrically connect to a second via section 324b2. The second via section 324b2 can extend through heavily doped semiconductor material 304b to electrically connect with conductive contact feature 308c2 which electrically connects to heavily doped semiconductor material 304a. The first via section 324b1 can extend through the two insulating bonding layers 306a, 306b deposited on the heavily doped semiconductor material 304c, and via section 324b2 can extend through the two insulating bonding layers 306a, 306b deposited on the heavily doped semiconductor material 304b. As explained herein, to provide the electrical connections, the conductive contact features and opposing bonding layers 306 can be hybrid bonded.

In some embodiments, the conductive contact features 308 and vias 324 may be formed into the semiconductor device 300 during formation of the layers 304a-304c and before the layers 304a-304c are bonded together using direct bonding techniques. For example, during formation of the layers 304a-304c that include the insulating bonding layers 306 and the heavily doped semiconductor material 304, the conductive contact features 308, vias 324, and the insulating rings 320 can be at least partially embedded in the heavily doped semiconductor material 304. The insulating layer 306 can be deposited on the surfaces of the semiconductor material 304, after which, the conductive contact features 308, vias 324, and the rings 320 are deposited into the etched trenches. In some embodiments, conductive contact features 302, 308, and 310 will be exposed to allow for electrical connections between the layers 304a-304c.

FIG. 3C depicts the semiconductor device 300 in which each heavily doped semiconductor material 304 is encapsulated by a first and second insulating bonding layer 306 and dielectric spacers 322 made from an insulating material. The dielectric spacers 322 can serve to laterally isolate the heavily doped semiconductor material 304 from laterally adjacent layers (not shown). In some embodiments, as in FIG. 3D, the first heavily doped semiconductor material 304a includes dielectric spacers 322. The dielectric spacers 322 separates the first heavily doped semiconductor material 304a into heavily doped semiconductor islands such as doped semiconductor islands. The dielectric spacers 322 allow each island to be connected to a different power or ground. For example, as shown in FIG. 3D, a first heavily doped semiconductor island 304a can be connected to a first power source at a first voltage, a second heavily doped semiconductor island 304d can be connected to a second power source at a second voltage, a third heavily doped semiconductor island 304e can be connected to a third power source at a third voltage, and a fourth heavily doped semiconductor island 304f can be connected to ground. In various embodiments, the second heavily doped semiconductor island 304d can connect the underlying die 102 (not shown) to the second power level by way of metal via 324b. The third heavily doped semiconductor island 304e can connect the die to the third power level by way of metal via 324f. Additional vias (not shown) can connect to the semiconductor islands 304a, 304f. In some embodiments, the heavily doped semiconductor islands 304a, 304d, 304e, and 304f are configured to connect to different electrical potentials. Accordingly, various embodiments disclosed herein enable for the routing of different potentials within a semiconductor layer 304. It should be appreciated that, although metal vias 324 are illustrated in FIG. 3D, in another embodiment, the conductive vias can comprise conductive semiconductor vias, which can be similar to the vias 310 described herein.

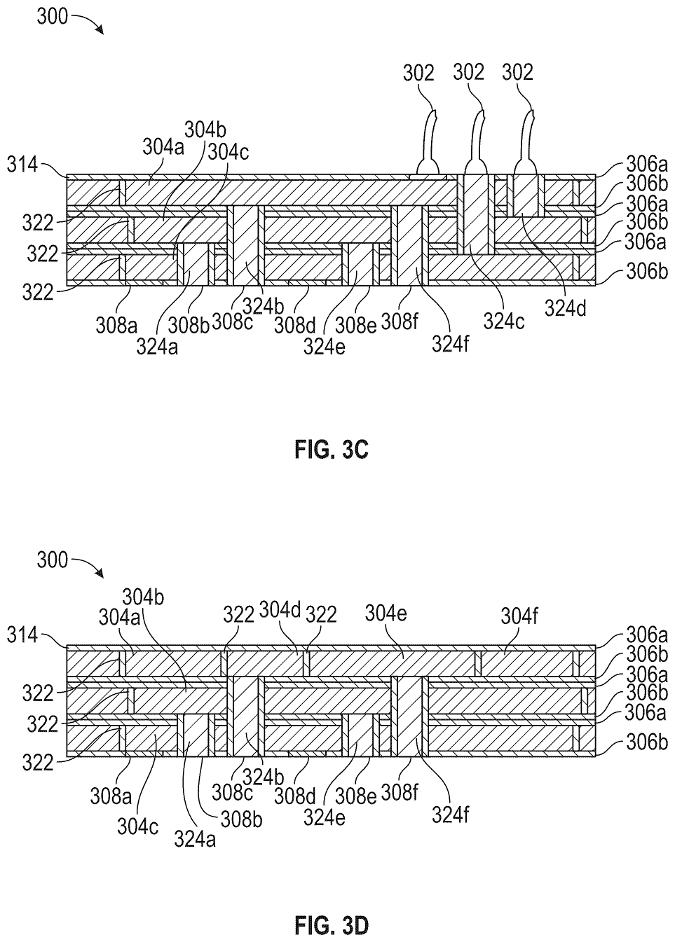

FIG. 4 is a schematic side sectional view of a semiconductor device 300 with heavily doped semiconductor materials 304 mounted to (e.g., directly hybrid bonded to) a back surface 406 of an integrated device die 402. The semiconductor device 300 includes one or more heavily doped semiconductor material layers 304 (e.g., semiconductor materials 304a-304c) as explained above. The one or more heavily doped semiconductor materials 304 can comprise insulating bonding layers 306 deposited on a top surface 314 and a bottom surface 316 opposite the top surface 314 of the heavily doped semiconductor materials 304. In some embodiments, dielectric spacers 322 extend from the insulating bonding layer 306 deposited at the top surface 314 to the insulating bonding layer 306 deposited at the bottom surface 316. The dielectric spacers 322 can function as insulating end caps to complete an enclosure that fully encapsulates the heavily doped semiconductor material 304 within insulating materials. Electrical pathways such as vias 324a-324e extend through selected layers 304 to provide electrical potential to each layer. The vias 324c and 324d receive electrical potential from inputs 302b, 302c, respectively, at conductive contact features 308h and 308i on the exposed ends of vias 324c and 324d. In some embodiments, a via is not used. For example, input 302a provides a first power to semiconductor material 304a through the conductive contact feature 308g without the use of a via. Additional vias 324a-324b and 324e-324f extend through the illustrated layers 304 to provide power from the heavily doped semiconductor layers 304 to the integrated device die 402 as explained above.

In some embodiments, an integrated device die 402 is connected to the semiconductor device 300 at the back surface 406 of the integrated device die 402. The semiconductor device 300 and the integrated device die 402 in FIG. 4 are connected through hybrid bonding without the use of an intervening adhesive. For example, conductive features 404 (i.e., die conductive features) of the integrated device die 402 in the insulating bonding layer 306a (i.e., die insulating layer) of the die 402 can be directly bonded to corresponding conductive contact features 308a-308f (e.g., contact pads or vias) of the power delivery device 300.

In some embodiments, the integrated device die 402 includes a front surface 408 and a back surface 406. The front surface 408 is an active side that includes one or more transistors, the transistor(s) deposited nearer the front surface 408 than the back surface 406.

In some embodiments, an integrated device die 402 can receive inputs of multiple powers or grounds. For example, the first heavily doped semiconductor layer 304a can receive a first electrical potential (e.g., a first power) from the input 302a. The second heavily doped semiconductor layer 304b can be connected to a second electrical potential (e.g., ground) by input 302c. The third heavily doped semiconductor layer 304c can receive a third electrical potential (e.g., a second power) from the input 302b. The integrated device die 402 can be connected to the first power of the first heavily doped semiconductor material 304a through vias 324b, 324f and corresponding conductive contact features 308c and 308f. The illustrated vias 624 can comprise metal vias in the illustrated embodiment. Additionally or alternatively, some or all of the vias can be doped semiconductor vias.

The integrated device die 402 can be connected to ground from the second heavily doped semiconductor material 304b through vias 324a and 324e and corresponding conductive contact features 308b and 308e. The integrated device die 402 can be connected to the second power from the third heavily doped semiconductor material 304c through conductive contact features 308a and 308d. Beneficially, the embodiment of FIG. 4 can enable the delivery of power to a back surface 406 of the die 402 opposite the active front side, which can enable for increased signal connections at the front surface 408.

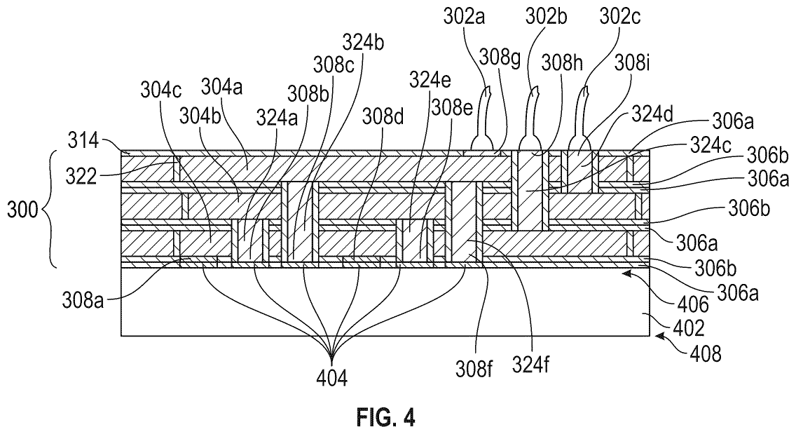

FIG. 5 is a schematic side sectional view of a semiconductor device 300 with heavily doped semiconductor materials 304 connected to a front surface 408 of an integrated device die 402. The semiconductor device 300 includes one or more heavily doped semiconductor materials 304 that are bonded together using insulating bonding layers 306 deposited on a top surface 314 and a bottom surface 316 of each heavily doped semiconductor materials 304. Conductive contact features 308 (i.e., device conductive features) electrically connect heavily doped semiconductor materials 304 to the integrated device die 402 with or without the use of a via 324. The conductive contact features 308 (e.g., discrete contact pads or exposed ends of vias) can directly bond with conductive features 504 embedded in the insulating bonding layer 306 deposited on the integrated device die 402. Corresponding insulating bonding layers 306 of the die 402 and the device 300 can directly bond to one another without an intervening adhesive. In some embodiments, the insulating bonding layer 306 on the integrated device die 402 can be deposited on a front surface 408 which is closer to transistors of the integrated device die 402 than the back surface 406.

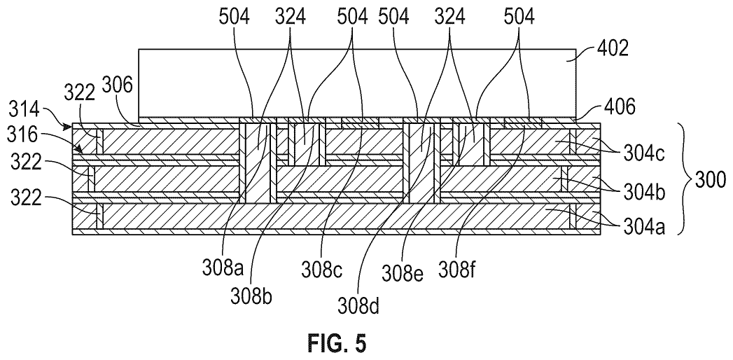

FIG. 6 is schematic side sectional view of a semiconductor device 600 with heavily doped semiconductor materials 304 connected to multiple integrated device dies 402 and a substrate 610. The semiconductor device 600 receives power from inputs 302 from a top surface 602 of the semiconductor device 600. In some embodiments, the semiconductor device 600 is connected to electrical potentials by inputs 302 and, in turn, may power a stack of integrated device dies 402 that are stacked on a top surface 602 and one or more underlying dies to which a bottom surface 604 of the device 600 is mounted. More than one integrated device 402 may be stacked on the heavily doped semiconductor device 600. In some embodiments, integrated device dies 402 may be attached by a front surface 408 or a back surface 406 of the integrated device die 402 to the semiconductor device 600 at the conductive contact features 308 using hybrid bonding.

For example, the semiconductor device 600 can be bonded with the back surface 406 of the integrated device die 402c, which is mounted on the substrate 610. The semiconductor device 600 receives electrical potential from the inputs 302 as described above and provides electrical potential to the integrated device dies 402b and/or 402c. The semiconductor device 600, using semiconductor materials 304 with a low CTE, can be attached to additional integrated device dies 402b and 402a that can be bonded to the semiconductor device 600 so as to reduce physical strain due to CTE mismatch. Accordingly, as explained above, die 402c can be mounted on (e.g., directly bonded to) substrate 610, and the power delivery device 600 can be mounted on (e.g., directly bonded to) the die 402c. The die 402c can comprise TSVs to provide electrical communication between the device 600 and the substrate 610. The die 402b can be mounted on (e.g., directly bonded to) the power delivery device 600, and the die 402a can be mounted to (e.g., directly bonded to) the die 402b. TSVs can be provided through die 402b to connect die 402a to the power delivery device 600.

In some embodiments, the semiconductor device 600 includes one or more thermal vias 608. The thermal via 608 of the semiconductor device 600 can provide a path for heat dissipation between the integrated device die 402b connected to one face of the semiconductor device 600 and the integrated device die 402c connected to an opposite face of the semiconductor device 600. The thermal via 608 can further improve heat dissipation to avoid thermally induced strains in the dies 402a-402b or the device 600.

The thermal via 608 can extend through the semiconductor device 600 to connect the two integrated device dies 402b and 402c. The thermal via 608 connection provides a pathway for heat to disperse from the integrated device die 402b to the die 402c. As the heat dissipates through the thermal via 608, the integrated device dies 402 can return to lower temperatures which will reduce mechanical strain on the semiconductor device 600 and dies 402a-402c. Further, although not shown, additional thermal vias can be provided through the lower die 402c to dissipate heat through the die 402c to a substrate 610. The semiconductor device 600 may be created or configured using any of the above listed configurations.

In some embodiments, the semiconductor device 600 and the integrated device dies 402 may be stacked on the substrate 610. The substrate 610 can be used by the integrated device die 402 to connect to an external device, such as a system board. For example, the substrate 610 may be connected to an external device that provides additional power or ground (and signals) and can pass the power and ground (and signals) to the integrated device die 402c.

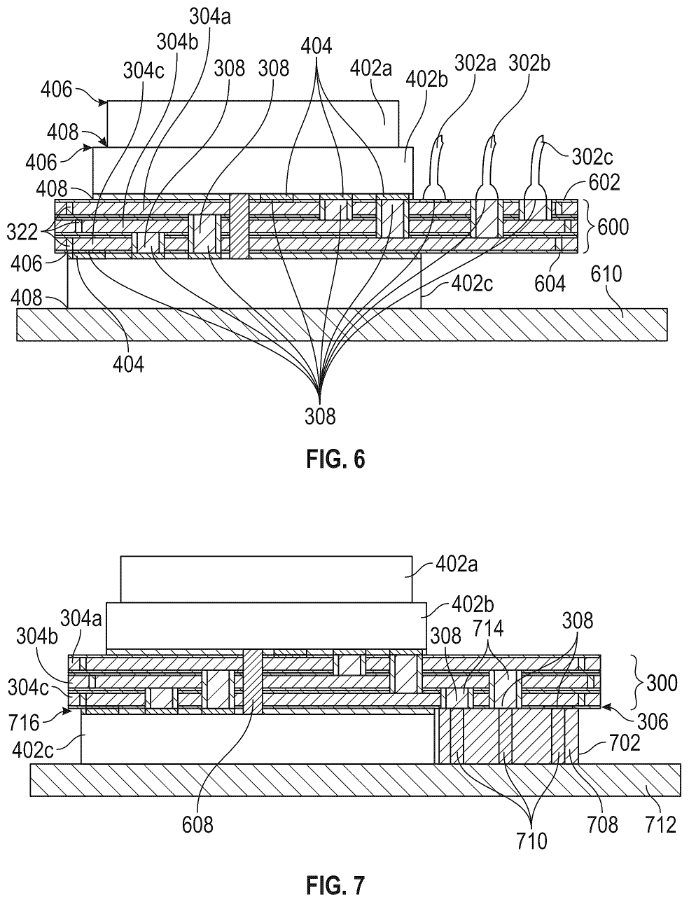

FIG. 7 is schematic side sectional view of a semiconductor power delivery device 700 with heavily doped semiconductor materials 304 connected to multiple integrated device dies 402 and a substrate 712. The substrate 712 provides the semiconductor device with power and ground through a connector block 702 from a bottom of the semiconductor device 700. The semiconductor device 700 can be configured using any of the above-mentioned embodiments. The connector block 702 can further include input conductors 710 extending through the conductor block 702 to connect to the substrate 712. The connector block 702 can include an insulating material 708 with embedded input conductors 710 that connect the substrate 712 with the heavily doped semiconductor layers 304 by way of contact features 308 and vias 714 (which can comprise metal vias or heavily doped semiconductor vias). Accordingly, in FIG. 7, the substrate 712 can supply power and/or ground to the input conductors 710 in the connector block 702, which in turn supplies the power and/or ground to the semiconductor power delivery device 700.

In some embodiments, the semiconductor device 700 may receive input from an input device and an interposer. In some embodiments, the interposer may provide power to the semiconductor device 700 and at least one integrated device die 402 simultaneously.

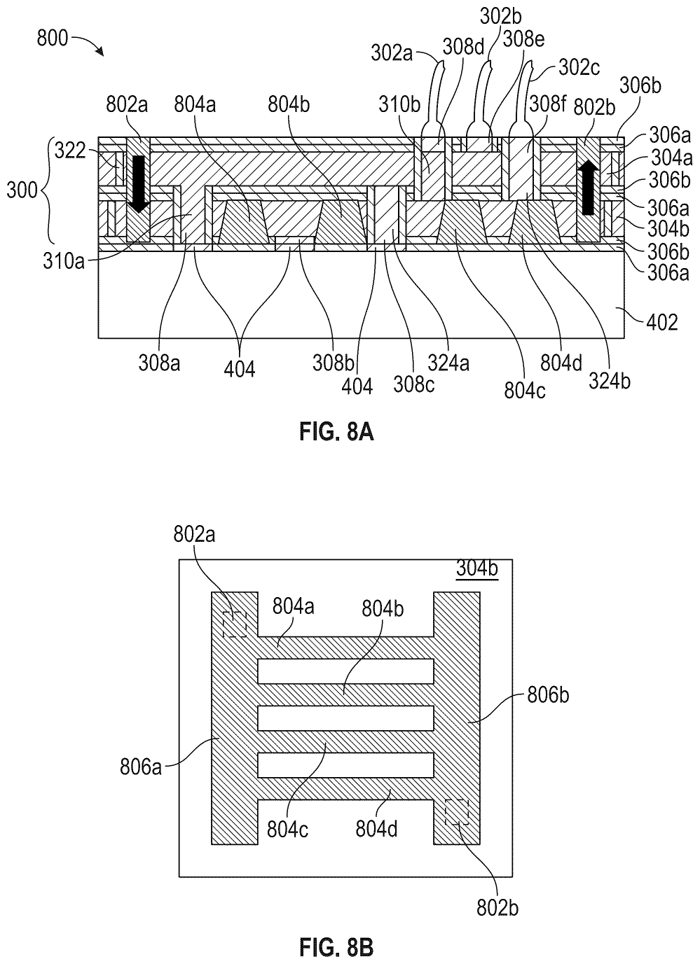

FIG. 8A is a schematic side sectional view of a semiconductor device 800 with heavily doped semiconductor materials 304 temperature controlled by a cooling device comprising cooling channels 804a-804d and mounted to (e.g., directly hybrid bonded to) an integrated device die 402. The semiconductor device 300 includes one or more heavily doped semiconductor material layers 304 (e.g., semiconductor materials 304a-304c) as explained above. The one or more heavily doped semiconductor materials 304 can be cooled by the cooling channels 804 extending through one or more of the heavily doped semiconductor materials 304. For example, as depicted in FIG. 8A, the cooling channels 804 can be cavities within the heavily doped semiconductor materials 304. The cavities can be formed in any suitable manner, e.g., by etching, drilling, etc. A cooing material can be provided into the cooling channels 804 at a cooling inlet 802a (e.g., a fluid inlet). From there, the cooling material can flow through the cooling channels 804 and out through a cooling outlet 802b (e.g., a fluid outlet). As the cooling material travels through the cooling channels 804, the cooling material can, through thermal conduction, lower the temperature of the heavily doped semiconductor layers 304 through which it extends and/or lower the temperature of the underlying die 402. Cooling materials can include liquids such as dielectric fluids that are not electrically conductive. As shown, the cooling materials can contact bonding layer 306a disposed on the die 402.

In some embodiments, the heavily doped semiconductor layers 304 are connected to electrical potentials through the vias 324, 310 as discussed in FIG. 4.

Electrical pathways such as the vias 324a-324b extend through selected layers 304 to provide electrical potential to each layer as explained above. The via 324b receives electrical potential from the input 302c at the conductive contact features 308f on the exposed ends of via 324b. In some embodiments, a via is not used. For example, the input 302a provides a first potential or power to semiconductor material 304a through the conductive contact feature 308e by way of a contact pad through the bonding layers 306b, 306a. Additional vias 324a and 310a and 310b (which can be metal vias, or alternatively, heavily doped semiconductor vias) extend through the illustrated layers 304 to provide power from the heavily doped semiconductor layers 304 to the integrated device die 402 as explained above. In some embodiments, the fluid flowing through the cooling channels 804 can comprise a nonconductive or dielectric fluid.

In some embodiments, the cooling channels 804 can extend through the insulating bonding layer 306b of a heavily doped semiconductor layer 304b. In this and other embodiments, the cavities of the cooling channels 804 can be encapsulated in a barrier that separates the cooling material from the heavily doped semiconductor layers 304 and other features of the semiconductor device 300. For example, a barrier around the cavity of cooling channel 804d can enclose the cooling material and prevent the cooling material flowing within the cooling channel 804d from coming into contact with the via 324d and potentially shorting the electrical connection with the heavily doped semiconductor layer 304b.

In some embodiments, an integrated device die 402 is connected to the semiconductor device 300 at the back surface 406 of the integrated device die 402. The semiconductor device 300 and the integrated device die 402 in FIG. 8A are connected through direct hybrid bonding without the use of an adhesive. In such embodiments, the integrated device die 402 can be separated from the cooling channels by the insulating bonding layer 306a. In some embodiments, the integrated bonding layer 306a can be made of a material that permits thermally conductive cooling from the cooling channels 804b of the integrated device die 402. In some embodiments, the integrated bonding layer 306 enables the cooling channels 804 to adjust the temperature of the integrated device die 402, lowering the temperature of the integrated device die 402.

FIG. 8B is a schematic top view of a semiconductor device 300 with heavily doped semiconductor materials temperature controlled by the cooling channels 804 extending through a single heavily doped semiconductor layer 304 such as the heavily doped semiconductor layer 304b of FIG. 8A. A cooling material can enter a cooling inlet channel 806a at a cooling inlet 802a from an external cooling source. The cooling channels 804 extend non-parallel relative to (e.g., perpendicularly to) the cooling inlet channel 806a, connecting the cooling inlet channel 806a to a cooling outlet channel 806b. The cooling material can exit the semiconductor device 300 through a cooling outlet 802b of the cooling outlet channel 806b. As described above, the cooling channels 804 and 806 can be encapsulated by a barrier that prevents the cooling material from affecting the electrical functionality of the heavily doped semiconductor layer 304b. In various embodiments, during operation of the system, one or more pumps can pump the cooling fluid through the cooling channels in a continuous or semi-continuous flow mode to cool the semiconductor device and/or die 402.

### Examples of Direct Bonding Methods and Directly Bonded Structures

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

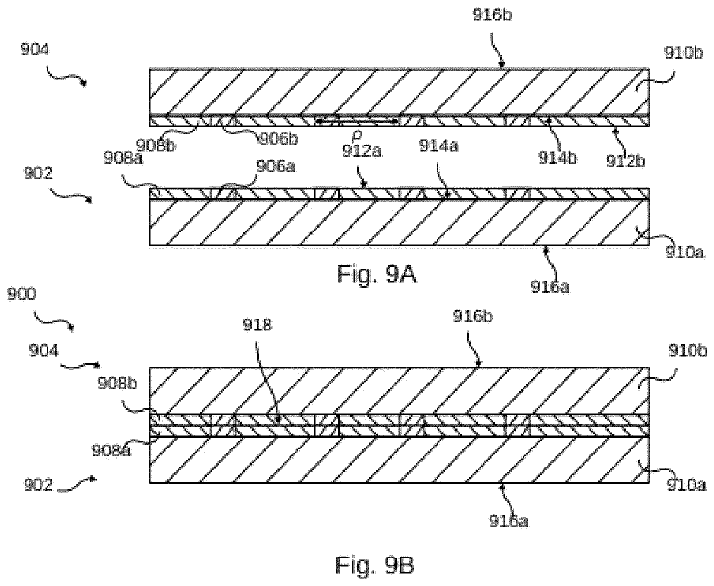

FIGS. 9A and 9B schematically illustrate cross-sectional side views of first and second elements 902, 904 prior to and after, respectively, a process for forming a directly bonded structure, and more particularly a hybrid bonded structure, according to some embodiments. In FIG. 9B, a bonded structure 900 comprises the first and second elements 902 and 904 that are directly bonded to one another at a bond interface 918 without an intervening adhesive. Conductive features 906a of a first element 902 may be electrically connected to corresponding conductive features 906b of a second element 904. In the illustrated hybrid bonded structure 900, the conductive features 906a are directly bonded to the corresponding conductive features 906b without intervening solder or conductive adhesive.

The conductive features 906a and 906b of the illustrated embodiment are embedded in, and can be considered part of, a first bonding layer 908a of the first element 902 and a second bonding layer 908b of the second element 904, respectively. Field regions of the bonding layers 908a, 908b extend between and partially or fully surround the conductive features 906a, 906b. The bonding layers 908a, 908b can comprise layers of non-conductive materials suitable for direct bonding, as described above, and the field regions are directly bonded to one another without an adhesive. The non-conductive bonding layers 908a, 908b can be disposed on respective front sides 914a, 914b of base substrate portions 910a, 910b.

The first and second elements 902, 904 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 902, 104, and back-end-of-line (BEOL) interconnect layers over such semiconductor portions. The bonding layers 908a, 908b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 910a, 910b, and can electrically communicate with at least some of the conductive features 906a, 906b. Active devices and/or circuitry can be disposed at or near the front sides 914a, 914b of the base substrate portions 910a, 910b, and/or at or near opposite backsides 916a, 916b of the base substrate portions 910a, 910b. In other embodiments, the base substrate portions 910a, 910b may not include active circuitry, but may instead comprise dummy substrates, passive interposers, passive optical elements (e.g., glass substrates, gratings, lenses), etc. The bonding layers 908a, 908b are shown as being provided on the front sides of the elements, but similar bonding layers can be additionally or alternatively provided on the back sides of the elements.

In some embodiments, the base substrate portions 910a, 910b can have significantly different coefficients of thermal expansion (CTEs), and bonding elements that include such different based substrate portions can form a heterogenous bonded structure. The CTE difference between the base substrate portions 910a and 910b, and particularly between bulk semiconductor (typically single crystal) portions of the base substrate portions 910a, 910b, can be greater than 5 ppm/° C. or greater than 10 ppm/° C. For example, the CTE difference between the base substrate portions 910a and 910b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 910a, 910b can comprise optoelectronic single crystal materials, including perovskite materials, that are useful for optical piezoelectric or pyroelectric applications, and the other of the base substrate portions 910a, 910b comprises a more conventional substrate material. For example, one of the base substrate portions 910a, 910b comprises lithium tantalate (LiTaO3) or lithium niobate (LiNbO3), and the other one of the base substrate portions 910a, 910b comprises silicon (Si), quartz, fused silica glass, sapphire, or a glass. In other embodiments, one of the base substrate portions 910a, 910b comprises a III-V single semiconductor material, such as gallium arsenide (GaAs) or gallium nitride (GaN), and the other one of the base substrate portions 910a, 910b can comprise a non-III-V semiconductor material, such as silicon (Si), or can comprise other materials with similar CTE, such as quartz, fused silica glass, sapphire, or a glass. In still other embodiments, one of the base substrate portions 910a, 910b comprises a semiconductor material and the other of the base substrate portions 910a, 910b comprises a packaging material, such as a glass, organic or ceramic substrate.

In some arrangements, the first element 902 can comprise a singulated element, such as a singulated integrated device die. In other arrangements, the first element 902 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 904 can comprise a singulated element, such as a singulated integrated device die. In other arrangements, the second element 904 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 902, 904 are shown, any suitable number of elements can be stacked in the bonded structure 900. For example, a third element (not shown) can be stacked on the second element 904, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 902. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 908a, 908b, the bonding layers 908a, 908b can be prepared for direct bonding. Non-conductive bonding surfaces 912a, 912b at the upper or exterior surfaces of the bonding layers 908a, 908b can be prepared for direct bonding by polishing, for example, by chemical mechanical polishing (CMP). The roughness of the polished bonding surfaces 912a, 912b can be less than 30 Å rms. For example, the roughness of the bonding surfaces 912a and 912b can be in a range of about 0.1 Å rms to 15 Å rms, 0.5 Å rms to 10 Å rms, or 1 Å rms to 5 Å rms. Polishing can also be tuned to leave the conductive features 906a, 906b recessed relative to the field regions of the bonding layers 908a, 908b.

Preparation for direct bonding can also include cleaning and exposing one or both of the bonding surfaces 912a, 912b to a plasma and/or etchants to activate at least one of the surfaces 912a, 912b. In some embodiments, one or both of the surfaces 912a, 912b can be terminated with a species after activation or during activation (e.g., during the plasma and/or etch processes). Without being limited by theory, in some embodiments, the activation process can be performed to break chemical bonds at the bonding surface(s) 912a, 912b, and the termination process can provide additional chemical species at the bonding surface(s) 912a, 912b that alters the chemical bond and/or improves the bonding energy during direct bonding. In some embodiments, the activation and termination are provided in the same step, e.g., a plasma to activate and terminate the surface(s) 912a, 912b. In other embodiments, one or both of the bonding surfaces 912a, 912b can be terminated in a separate treatment to provide the additional species for direct bonding. In various embodiments, the terminating species can comprise nitrogen. For example, in some embodiments, the bonding surface(s) 912a, 912b can be exposed to a nitrogen-containing plasma. Other terminating species can be suitable for improving bonding energy, depending upon the materials of the bonding surfaces 912a, 912b. Further, in some embodiments, the bonding surface(s) 912a, 912b can be exposed to fluorine. For example, there may be one or multiple fluorine concentration peaks at or near a bond interface 918 between the first and second elements 902, 904. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 900, the bond interface 918 between two non-conductive materials (e.g., the bonding layers 908a, 908b) can comprise a very smooth interface with higher nitrogen (or other terminating species) content and/or fluorine concentration peaks at the bond interface 918. In some embodiments, the nitrogen and/or fluorine concentration peaks may be detected using various types of inspection techniques, such as SIMS techniques. The polished bonding surfaces 912a and 912b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 908a and 908b can be directly bonded to one another without an adhesive. In some embodiments, the elements 902, 904 are brought together at room temperature, without the need for application of a voltage, and without the need for application of external pressure or force beyond that used to initiate contact between the two elements 902, 904. Contact alone can cause direct bonding between the non-conductive surfaces of the bonding layers 908a, 908b (e.g., covalent dielectric bonding). Subsequent annealing of the bonded structure 900 can cause the conductive features 906a, 906b to directly bond.

In some embodiments, prior to direct bonding, the conductive features 906a, 906b are recessed relative to the surrounding field regions, such that a total gap between opposing contacts after dielectric bonding and prior to anneal is less than 15 nm, or less than 10 nm. Because the recess depths for the conductive features 906a and 906b can vary across each element, due to process variation, the noted gap can represent a maximum or an average gap between corresponding conductive features 906a, 906b of two joined elements (prior to anneal). Upon annealing, the conductive features 906a and 906b can expand and contact one another to form a metal-to-metal direct bond.

During annealing, the conductive features 906a, 906b (e.g., metallic material) can expand while the direct bonds between surrounding non-conductive materials of the bonding layers 908a, 908b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 906a, 906b can comprise discrete pads, contacts, electrodes, or traces at least partially embedded in the non-conductive field regions of the bonding layers 908a, 908b. In some embodiments, the conductive features 906a, 906b can comprise exposed contact surfaces of TSVs (e.g., through silicon vias).

As noted above, in some embodiments, in the elements 902, 904 of FIG. 9A prior to direct bonding, portions of the respective conductive features 906a and 906b can be recessed below the non-conductive bonding surfaces 912a and 912b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 906a, 906b or to average depths of the recesses relative to local non-conductive field regions. Even for an individual conductive feature 906a, 906b, the vertical recess can vary across the feature, and so can be measured at or near the lateral middle or center of the cavity in which a given conductive feature 906a, 906b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 906a, 906b across the direct bond interface 918 (e.g., small or fine pitches for regular arrays).

In some embodiments, a pitch p of the conductive features 906a, 906b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 906a and 906b to one of the lateral dimensions (e.g., a diameter) of the bonding pad is less than is less than 20, or less than 10, or less than 5, or less than 3 and sometimes desirably less than 2. In various embodiments, the conductive features 906a and 906b and/or traces can comprise copper or copper alloys, although other metals may be suitable, such as nickel, aluminum, or alloys thereof. The conductive features disclosed herein, such as the conductive features 906a and 906b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 902, 904, as shown, the orientations of one or more conductive features 906a, 906b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 906b in the bonding layer 908b (and/or at least one internal conductive feature, such as a BEOL feature) of the upper element 904 may be tapered or narrowed upwardly, away from the bonding surface 912b. By way of contrast, at least one conductive feature 906a in the bonding layer 908a (and/or at least one internal conductive feature, such as a BEOL feature) of the lower element 902 may be tapered or narrowed downwardly, away from the bonding surface 912a. Similarly, any bonding layers (not shown) on the backsides 916a, 916b of the elements 902, 904 may taper or narrow away from the backsides, with an opposite taper orientation relative to front side conductive features 906a, 906b of the same element.

As described above, in an anneal phase of hybrid bonding, the conductive features 906a, 906b can expand and contact one another to form a metal-to-metal direct bond. In some embodiments, the materials of the conductive features 906a, 906b of opposite elements 902, 904 can interdiffuse during the annealing process. In some embodiments, metal grains grow into each other across the bond interface 918. In some embodiments, the metal is or includes copper, which can have grains oriented along the 111 crystal plane for improved copper diffusion across the bond interface 918. In some embodiments, the conductive features 906a and 906b may include nanotwinned copper grain structure, which can aid in merging the conductive features during anneal. There is substantially no gap between the non-conductive bonding layers 908a and 908b at or near the bonded conductive features 906a and 906b. In some embodiments, a barrier layer may be provided under and/or laterally surrounding the conductive features 906a and 906b (e.g., which may include copper). In other embodiments, however, there may be no barrier layer under the conductive features 906a and 906b.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A semiconductor device, comprising:
a first layer comprising a first heavily doped semiconductor material and a first insulating bonding layer;
a second layer comprising a second heavily doped semiconductor material and a second insulating bonding layer; and
a first via extending through the second layer and electrically connecting to the first heavily doped semiconductor material,
wherein the first layer and the second layer are directly bonded to one another without an intervening adhesive.

2. The semiconductor device of claim 1, wherein the first via connects one of power or ground to the first heavily doped semiconductor material of the first layer.

3. The semiconductor device of claim 1, wherein the first layer further comprises first conductive features and the second layer further comprises second conductive features, wherein the first conductive features and the second conductive features are directly bonded to one another without an intervening adhesive.

4. The semiconductor device of claim 3, wherein the second layer is hybrid bonded to the first layer such that the second insulating bonding layer of the second layer is directly bonded to the first insulating bonding layer of the first layer, and the second conductive features of the second layer are directly bonded to the first conductive features of the first layer.

5. The semiconductor device of claim 1, further comprising a third layer comprising a third heavily doped semiconductor material and a third insulating bonding layer, wherein the second layer and the third layer are directly bonded to one another without an intervening adhesive.

6. (canceled)

7. The semiconductor device of claim 1, wherein the first heavily doped semiconductor material is embedded with dielectric spacers, the dielectric spacers separating the first heavily doped semiconductor material into heavily doped semiconductor islands, wherein the heavily doped semiconductor islands are configured to connect to different electrical potentials.

8. (canceled)

9. (canceled)

10. The semiconductor device of claim 1, wherein the second heavily doped semiconductor material is connected to electrical ground.

11. (canceled)

12. The semiconductor device of claim 1, wherein each of the first and second heavily doped semiconductor materials has a dopant concentration of at least 10¹⁸ atoms/cm³ and less than 10²² atoms/cm³.

13. The semiconductor device of claim 1, further comprising: a fluid inlet;
an inlet channel connected to the fluid inlet; a fluid outlet;
an outlet channel connected to the outlet; and
one or more cooling channels extending through at least the first insulating layer, wherein the one or more cooling channels connect to the inlet channel and the outlet channel.

14. The semiconductor device of claim 13, wherein the inlet, the inlet channel, and the one or more cooling channels are arranged to allow a fluid to flow into the semiconductor device such that the inlet channel and the one or more cooling channels integrally connect such that the fluid can flow from the inlet channel to the one or more cooling channels.

15. The semiconductor device of claim 13, wherein the outlet, the outlet channel, and the one or more cooling channels are arranged to allow a fluid to flow from the semiconductor device such that the one or more cooling channels and the outlet channel integrally connect such that the fluid can flow from the one or more cooling channels to the outlet channel to exit the semiconductor device at the outlet.

16. The semiconductor device of claim 13, wherein the inlet, the inlet channel, the outlet, the outlet channel, and the one or more cooling channels include a cavity, wherein the cavity encloses a cooling fluid.

17. The semiconductor device of claim 16, wherein the cooling fluid is a dielectric fluid.

18. (canceled)

19. A bonded structure including the semiconductor device of claim 1, the bonded structure further comprising an integrated device die, the integrated device die comprising a front surface and a back surface, wherein the semiconductor device is directly bonded to the integrated device die.

20. A bonded structure comprising:
a first integrated device die comprising a front surface and a back surface, the first integrated device die including a die insulating layer and a die conductive feature at least partially embedded in the die insulating layer; and
a semiconductor device having a first surface and a second surface opposite the first surface, the semiconductor device including a first insulating layer on the first surface, a device conductive feature at least partially embedded in the first insulating layer, and a first heavily doped semiconductor material electrically connected to the device conductive feature, the first insulating layer directly bonded to the die insulating layer without an intervening adhesive, and the die conductive feature directly bonded to the device conductive feature without an intervening adhesive,
wherein the die conductive feature is connected to power or ground through at least the first heavily doped semiconductor material.

21. The bonded structure of claim 20, wherein the front surface of the first integrated device die is an active side that includes one or more transistors, the one or more transistors being disposed nearer the front surface than the back surface.

22. (canceled)

23. The bonded structure of claim 20, wherein the semiconductor device includes a second heavily doped semiconductor material disposed over the first heavily doped semiconductor material, wherein the first heavily doped semiconductor material is connected to one of a first power or ground and the second heavily doped semiconductor material is connected to one of a second power or ground, the first and second heavily doped semiconductor materials electrically connected to the first integrated device die.

24. (canceled)

25. (canceled)

26. (canceled)

27. (canceled)

28. The bonded structure of claim 20, further comprising:
a fluid inlet;
an inlet channel connected to the fluid inlet;
a fluid outlet;
an outlet channel connected to the outlet; and
one or more cooling channels extending through at least the first insulating layer, wherein the one or more cooling channels connect to the inlet channel and the outlet channel.

29. (canceled)

30. (canceled)

31. (canceled)

32. (canceled)

33. (canceled)

34. (canceled)

35. (canceled)

36. (canceled)

37. A bonded structure comprising:
a heavily doped semiconductor material having a first insulating bonding layer on a first surface of the heavily doped semiconductor material and first conductive features at least partially embedded in the first insulating bonding layer; and
an electronic component having a second insulating bonding layer and second conductive features at least partially embedded in the second insulating bonding layer, the first insulating bonding layer directly bonded with the second insulating bonding layer without an intervening adhesive, the first conductive features directly bonded with the second conductive features without an intervening adhesive,
wherein the heavily doped semiconductor material has a coefficient of thermal expansion (CTE) within 50% to 150% of a CTE of a device portion of the electronic component.

38. The bonded structure of claim 37, wherein the heavily doped semiconductor material comprises silicon.
